(19) United States
(12) Patent Application Publication
(10) Pub. No.: US 2002/0154484 A1
(43) Pub. Date: Oct. 24, 2002

(54) Element for attaching a heat shield

(76) Inventor: Bruno Gorlich, Weibenhorn (DE)

Correspondence Address: RADER, FISHMAN & GRAUER PLLC, 39533 WOODWARD AVENUE, SUITE 140, BLOOMFIELD HILLS, MI, 48304-0610, US

(21) Appl. No.: 10/103,000

(22) Filed: Mar. 21, 2002

(30) Foreign Application Priority Data
Mar. 23, 2001 (DE) 101 14 295.1

(51) Int. Cl. H05K 7/20

(52) U.S. Cl. 361/704

(57) ABSTRACT

The invention pertains to a heat-shield attachment element with a through-hole for an attachment element, wherein the heat-shield attachment element is formed from at least one flanged tube (2) and another element (3, 5) provided with a flange (3′, 5′); in this way, there is a through-hole in the flanged tube (2) and the other element (3, 5); the flanged tube (2) is inserted into a hole formed in the heat shield (1) and the flange (2′) of the flanged tube (2) contacts one side of the heat shield and the other element (3, 5) contacts the opposite side of the heat shield (1) over an area.

The invention pertains to a heat-shield attachment element that can be used for reliable attachment of heat shields in spaces for motors in motor vehicles.

Heat shields are used in various forms for sound and heat insulation while taking into account a wide range of installation and operating conditions in spaces for motors in motor vehicles. Above all, they are used for protection of temperature-sensitive components and systems in order to prevent overheating, e.g., due to heat given off by the exhaust system.

For such heat shields, a wide range of constructions is known, e.g., single-layer or multi-layer formed bodies that can be manufactured from different materials.

Generally, such heat shields are attached by means of conventional threaded fasteners. However, these connections must take into account the tightness and stability required for each heat shield and also the oscillations affecting the location of the installation, in order to prevent damage to the heat shield and the undesired detachment of such threaded fasteners.

However, through the use of materials and the construction of the heat shields, the tightening torque of the screws cannot be set excessively high in order to prevent damage to the heat shield.

Consequently, the cost-effective and simple solutions that use screws with disk rings or spring rings are also limited because they merely allow a reduction of surface pressure and the forces are passed directly into the heat-shield material. Also, the use of several unconnected individual parts to attach the heat shields naturally increases the assembly effort.

Therefore, the objective of the invention is to disclose a heat-shield attachment element that is simple to construct and that can be manufactured with a cost-effective procedure, wherein the mechanical loading of the heat shield to be attached is reduced in the attachment region.

This objective is realized according to the invention with a heat-shield attachment element that has the features of claim 1. Advantageous embodiments and refinements of the invention can be achieved with the features mentioned in the subordinate claims.

The heat-shield attachment element according to the invention has a through-hole for an attachment element, e.g., a conventional screw, with which a heat shield can be attached inside a space for a motor in a motor vehicle.

The heat-shield attachment element is essentially formed from two parts.

One essential element is a flanged tube with a tube-shaped part that is guided through a hole formed in the heat shield such that the tube-shaped part of this flanged tube forms the through-hole for the corresponding attachment element.

After the insertion of this flanged tube through the hole in the heat shield, the flange contacts one side of the heat shield over an area and the tube-shaped part of this flanged tube projects through the hole in the heat shield to the opposite surface of the heat shield. At this side there is a second element that is likewise provided with a through-hole and a flange and that, in turn, contacts this side of the heat shield over an area.

If a screw as an attachment element is tightened, then the tightening torque of the screw acts with the corresponding contact forces exclusively on the flange of at least one flanged tube and on the second element arranged on the opposite side of the heat shield, so that the part of the heat shield between these elements is merely arranged in a secondary flux of force, wherein if the flanged tube and the second element are dimensioned correspondingly, a relatively small contact force acts on the heat-shield material and the heat-shield attachment element according to the invention and the heat shield is gripped on two sides and held as in a clamp.

In a variant, the already mentioned second element can also be formed in the shape of a flanged tube, wherein the flange of the second flanged tube is arranged parallel to the flange of the first flanged tube on the corresponding opposite side of the heat shield. The inner diameter of the tube-shaped part of this second flanged tube is thus chosen correspondingly larger, so that when it is inserted into the correspondingly larger hole of the heat shield, the tube-shaped part of the second flanged tube can grip the tube-shaped part of the first flanged tube at its radially outer edge; thus, the two flanged tubes can be set one inside the other.

The two flanged tubes should be dimensioned, particularly with their tube-shaped parts, so that in the assembled position, they can form flat contact surfaces on both sides of the heat shield. This pertains particularly to the side of the heat-shield attachment element, towards which the first flanged tube extends with its tube-shaped part that simultaneously forms the through-hole for the corresponding attachment element.

In another variant, an annular flanged disk can be used as the second element with a flange instead of the second flanged tube. For this flanged disk, the corresponding flange is arranged projecting radially inwards and represents an annular tapering of the thickness of this flanged disk. Then, in the assembled state, the flange of this flanged disk is aligned parallel to the outer contact surface of the tube-shaped part of the first flanged tube and after inserting a screw as an attachment element, the flange is in direct contact with this contact surface of the tube-shaped part of the first flanged tube, so that, as required by the design, a limit to the contact force is set in order to prevent damage to the heat shield. The same effect can also be achieved for the variant with the two flanged tubes, wherein the tube-shaped parts of the two flanged tubes are dimensioned accordingly.

Both the flanged tubes to be used according to the invention and also the flanged disks are parts that can be manufactured with a cost-effective procedure and that can be made, e.g., from a suitable metal.

Advantageously, the two parts, as two flanged tubes or one flanged tube with a flanged disk, can be connected by means of a press fit and can be attached simultaneously to the corresponding heat shield. By means of such a press fit, the two parts can then still undergo slight relative movements for the tightening of a screw for attaching the heat shield, without breaking the connection. Nevertheless, sufficient transport safety before installation of the heat shields can be guaranteed.

Obviously, these parts can also be connected, at least temporarily, by means of other forms, as can be the case, e.g., through gluing or soldering.

It is advantageous to connect these parts with a positive fit in order to prevent the loss of a part. In addition, expansion due to heat, e.g., at the bend of an exhaust system, and/or vibrations can be compensated for and damage to the heat shield prevented, wherein this can be preferably achieved with the formation of the through-hole in the form of an oblong hole, so that the clearance for movements cannot directly affect the attachment.

In the following, the invention will be explained in more detail with reference to embodiments.

Shown are:

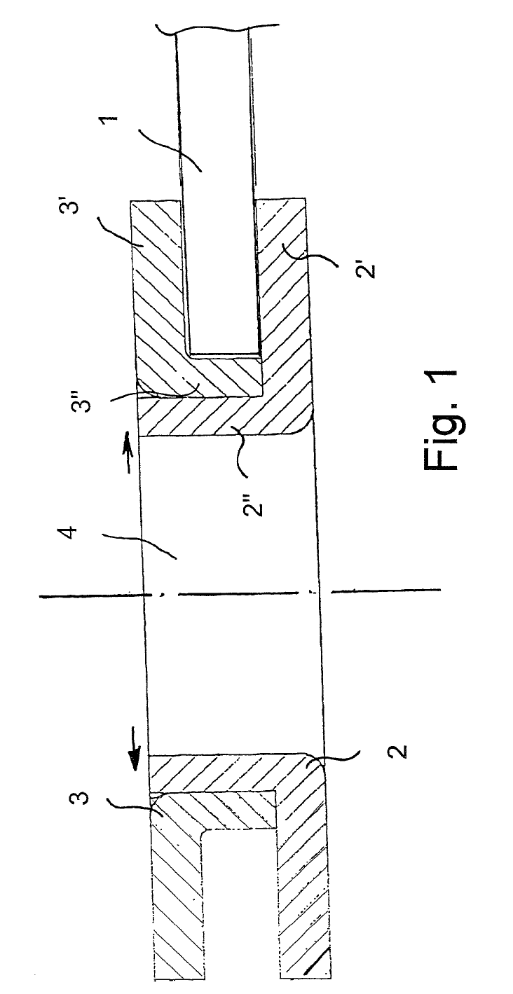

FIG. 1, an example of a heat-shield attachment element according to the invention with two flanged tubes in a cross section, and

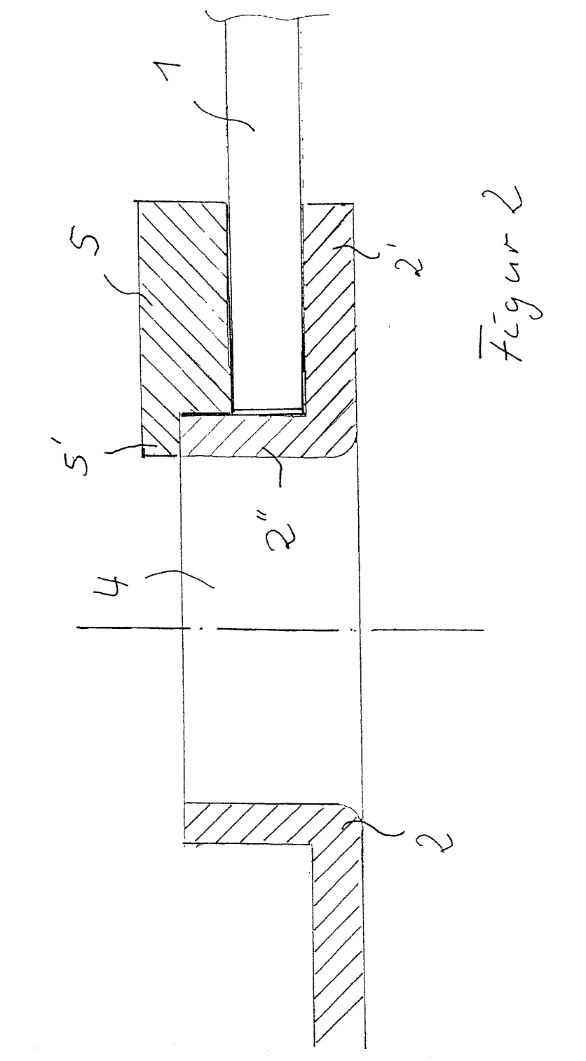

FIG. 2, an example of a heat-shield attachment element according to the invention with a flanged tube and a flanged disk in a cross section.

FIG. 1 shows an example of a heat shield according to the invention with two flanged tubes 2 and 3 that are arranged on both sides of a heat shield 1.

Both flanged tubes 2 and 3 are guided through a hole formed in the heat shield 1 and set one in the other. In this way, the flange 2′ of the first flanged tube 2 and the flange 3′ of the second flanged tube 3 contact opposite sides of the heat shield 1 over an area. Therefore, a part of the heat shield 1 is clamped on both sides by the two flanges 2′ and 3′.

The inner diameter of the through-hole 4 is given by the tube-shaped part 2″ of the first flanged tube 2.

The outer diameter of the tube-shaped part 2″ of the first flanged tube and the inner diameter of the tube-shaped 3″ of the second flanged tube 3 are advantageously adapted to each other so that in the illustrated form, they form a press fit. The pressing force of this press fit allows relative motion of the two flanged tubes 2 and 3 parallel to the longitudinal axis of the through-hole 4 for tightening of a screw for attaching the heat shield. However, the pressing force is large enough that the loss of parts is prevented during transport of the heat shield with the heat-shield attachment element.

As can be seen in the illustration in FIG. 1, particularly the tube-shaped parts 2″ and 3″ of the two flanged tubes 2 and 3 are dimensioned so that the tightening of a screw for attaching the heat shield 1 limits the motion of the flanged tube 3, and, consequently, this also prevents excessive force on the heat shield material, which could lead to damage.

A form-fit connection of the two flanged tubes 2 and 3 is also advantageous. Such a form-fit connection can be achieved very simply through a deformation directed radially outwards in the outer face of the tube-shaped part 2″ of the first flanged tube 2, as indicated in FIG. 1 with the two arrows pointing radially outwards. The deformation can be achieved by means of a wedge or stamp, which is adapted to the form of the through-hole 4, if necessary, that of a circular pyramid or cone. Such a wedge or stamp is then pressed into the through-hole 4, wherein the flange 2″ is supported and the outer-face region of the tube-shaped part 2″ can be deformed radially outwards. Such a deformation can be realized at least at one point on the tube-shaped part 2″. However, two or more diametrically opposite deformations or a deformation encircling the entire extent of the through-hole 4 can also form the form-fit connection with the second flanged tube 3.

As can be seen in FIG. 1, the transition of the flange 3′ to the tube-shaped part 3″ can be rounded, so that the deformed regions of the tube-shaped part 2″ grip the rounded region of the second flanged tube 3 and thus guarantee the form-fit connection of the flanged tubes 2 and 3 assembled on the heat shield 1.

For the example shown in FIG. 2 of a heat-shield attachment element according to the invention, there is only one flanged tube 2, which in turn, is guided through a correspondingly dimensioned hole in the heat shield 1. The tube-shaped part 2″ of this flanged tube extends to the opposite side of the heat shield 1.

On this side there is an annular flanged disk, whose flange 5′ extends radially inwards and the flange 5′ is formed from the shape of a reduction in thickness of the flanged disk 5.

The surface of the flange 5′ of the flanged disk 5 extending in the direction of the flanged tube 2 is aligned parallel to the outer surface of the tube-shaped part 2″ of the flanged tube 2, and, after attaching the heat shield, it forms a direct contact with this outer surface, so that a limit is realized for the movement and consequently also for the force on the heat shield 1.

The outer diameter of the tube-shaped part 2″ of the flanged tube 2 and the inner diameter of the flanged disk 5, which is designed relative to the flanged disk 5, can be dimensioned again so that the already mentioned press fit can be guaranteed in this region.

1. Heat-shield attachment element with a through-hole for an attachment element, characterized in that the heat-shield attachment element is formed from at least one flanged tube (2) and another element (3, 5) provided with a flange (3′, 5′); in this way, there is a through-hole in the flanged tube (2) and the other element (3, 5); the flanged tube (2) is inserted into a hole formed in the heat shield (1), and the flange (2′) of the flanged tube (2) contacts one side of the heat shield and the other element (3, 5) contacts the opposite side of the heat shield (1) over an area.

2. Heat-shield attachment element according to claim 1, characterized in that the other element is a second flanged tube (3), whose flange (3′) is directed parallel to the flange (2′) of the first flanged tube (2), and the tube-shaped part (3″) of the second flanged tube (3) grips the tube-shaped part (2″) of the first flanged tube (2) at its radially outer edge.

3. Heat-shield attachment element according to claim 1 or 2, characterized in that the tube-shaped part (2″) is deformed radially outwards on the outer side of the first flanged tube (2) for forming a form-fit connection with the second flanged tube (3).

4. Heat-shield attachment element according to claim 1, characterized in that the other element is an annular flanged disk (5) and the flange (5′) of the flanged disk (5) is aligned parallel to the outer surface of the tube-shaped part (2″) of the first flanged tube (2), which is guided through the heat shield (1).

5. Heat-shield attachment element according to one of claims 1-4, characterized in that the inner diameter of the tube-shaped part (2″) and/or of the flanged disk (5) sets the inner diameter of the through-hole (4).

6. Heat-shield attachment element according to one of claims 1-5, characterized in that the first flanged tube (2) is connected by means of a press fit to the second flanged tube (3) or the flanged disk (5).

7. Heat-shield attachment element according to one of claims 1-6, characterized in that the through-hole (4) is formed in the shape of an oblong hole.
